(19) United States
(12) Patent Application Publication
(10) Pub. No.: US 2011/0089987 A1
(43) Pub. Date: Apr. 21, 2011

(54) MULTI-PHASE SIGNALS GENERATOR

(75) Inventor: Tzu-Cheng Yang, Taipei County (TW)

(73) Assignee: NOVATEK MICROELECTRONICS CORP., Hsinchu (TW)

(21) Appl. No.: 12/630,798

(22) Filed: Dec. 3, 2009

(30) Foreign Application Priority Data
Oct. 16, 2009 (TW) 98135148

(51) Int. Cl. G06F 1/04; H03K 21/00

(52) U.S. Cl. 327/295; 377/47

(57) ABSTRACT

A multi-phase signals generator is disclosed. The multi-phase signals generator mentioned above includes a frequency divider and N delay circuits. The frequency divider receives a clock signal and divides a frequency of the clock signal to generate a divided frequency clock signal. The N delay circuits are connected in series. The delay circuit connected in a first stage receives the divided frequency clock signal. The delay circuit connected in an i^{th} stage receives an output of the delay circuit connected in an (i−1)^{th} stage, wherein i is an integer larger than 2. The delay circuits respectively delay a received signal according to the clock signal and generate N delay output signals, wherein N is an integer larger than 3. Moreover, a plurality of times for transmitting the clock signal to all of the delay circuits are the same.

### CROSS-REFERENCE TO RELATED APPLICATION

This application claims the priority benefit of Taiwan application serial no. 98135148, filed on Oct. 16, 2009. The entirety of the above-mentioned patent application is hereby incorporated by reference herein and made a part of specification.

### BACKGROUND OF THE INVENTION

1. Field of the Invention

The present invention relates to a multi-phase signals generator. More particularly, the present invention relates to a multi-phase signals generator having a single-end input.

2. Description of Related Art

A conventional high-frequency multi-phase signals generator is generally constructed by a so-called current mode logic circuit. The current mode logic circuit receives differential inputs, and compares the currents generated on the circuit to generate a corresponding logic level output. The current mode logic circuit generally has a DC current path, which may cause a relatively large power consumption. Moreover, a circuit area of the current mode logic circuit is relatively large, so that it is not an optimal selection for the multi-phase signals generator.

With developments of fabrication techniques, a true single-phase clocking (TSPC) logic circuit can be operated under a giga hertz (GHz) level. Compared to the current mode logic circuit, the TSPC logic circuit has both of the advantages of power-saving and small circuit area, and can generate a nearly full swing output. Therefore, a plurality of four-phase signals generators designed base on the TSPC logic circuit is disclosed, recently.

Referring to FIG. 1A and FIG. 1B, FIG. 1A is a diagram illustrating a four-phase signals generator 110 disclosed by a U.S. Pat. No. 7,508,273. FIG. 1B is a diagram illustrating a divided-by-3 circuit 120 disclosed by a U.S. Pat. No. 6,389,095. Wherein, the four-phase signal generator 110 of FIG. 1A has to receive four different input signals Iin, Iin−, Qin and Qin− to generate output signals Iout, Iout−, Qout and Qout− having different phases through operations of a 4/3 circuit 111 and flip-flops DFF1 and DFF2. Moreover, the output signal Iout− is generated by an inverter (which is in the flip-flop DFF1) according to the output signal Iout, and the output signal Qout− is generated by an inverter (which is in the flip-flop DFF2) according to the output signal Qout. Therefore, the four-phase signal generator 110 may have problems of unequal amplitudes and limitation of a bandwidth, etc.

Moreover, the divided-by-3 circuit 120 of FIG. 1B requires differential input signals CLK_1 and CLK_Q, and two sets of same circuits to generate four output signals having different phases. In the divided-by-3 circuit 120 of FIG. 1B, the flip-flops are also required, so that the problems of unequal amplitudes and limitation of the bandwidth, etc. are also inevitable.

### SUMMARY OF THE INVENTION

The present invention is directed to a multi-phase signals generator, which can use a single-end input to generate multi-phase output signals.

The present invention provides a multi-phase signals generator including a frequency divider and N delay circuits. The frequency divider receives a clock signal and divides a frequency of the clock signal to generate a divided frequency clock signal. The N delay circuits are connected in series. The delay circuit connected in a first stage is coupled to the frequency divider and receives the divided frequency clock signal. The delay circuit connected in an stage receives an output of the delay circuit connected in an (i−1)^{th} stage, wherein i is an integer larger than 2. The delay circuits respectively delay a received signal according to the clock signal and generate N delay output signals, wherein N is an integer larger than 3. Moreover, the times for transmitting the clock signal to all of the delay circuits are the same.

In an embodiment of the present invention, the frequency divider performs a frequency dividing according to a rising edge of the clock signal, and the delay circuit generates one of the delay output signals according to a falling edge of the clock signal.

In an embodiment of the present invention, the frequency divider performs a frequency dividing according to a falling edge of the clock signal, and the delay circuit generates one of the delay output signals according to a rising edge of the clock signal.

In an embodiment of the present invention, a divisor provided by the frequency divider is equal to a positive integer multiplication of N.

In an embodiment of the present invention, the frequency divider includes at least N frequency-dividing units, and the frequency-dividing units receive the clock signal and divide the frequency of the clock signal to generate the divided frequency clock signal.

In an embodiment of the present invention, the frequency-dividing unit includes a T-type flip-flop. The T-type flip-flop has an input terminal and an output terminal, wherein the input terminal receives the clock signal, and the output terminal outputs the divided frequency clock signal.

In an embodiment of the present invention, the frequency-dividing unit includes a D-type flip-flop. The D-type flip-flop has an input terminal, an output terminal, an inverted output terminal and a clock terminal, wherein the input terminal is coupled to the inverted output terminal, and the output terminal outputs the divided frequency clock signal.

In an embodiment of the present invention, each of the delay circuits includes a D-type flip-flop. The D-type flip-flop has an input terminal, an output terminal and a clock terminal, wherein the clock terminal receives the clock signal, the input terminal receives one of the delay output signals or the divided frequency clock signal, and the output terminal outputs another one of the delay output signals.

In an embodiment of the present invention, the multi-phase signals generator further includes N output buffers. The output buffers are respectively coupled to the delay circuits. The delay circuits receive the delay output signals to generate N multi-phase output signals.

According to the above descriptions, in the present invention, the frequency dividing and the signal delay are performed according to the single-end input clock signal, so as to generate a plurality of the multi-phase output signals having different phases. In the present invention, using of the differential inputs required by the conventional current mode logic circuit is avoided, so that a power consumption of the DC current can be effectively reduced.

In order to make the aforementioned and other features and advantages of the present invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a diagram illustrating a four-phase signals generator 110 disclosed by a U.S. Pat. No. 7,508,273.

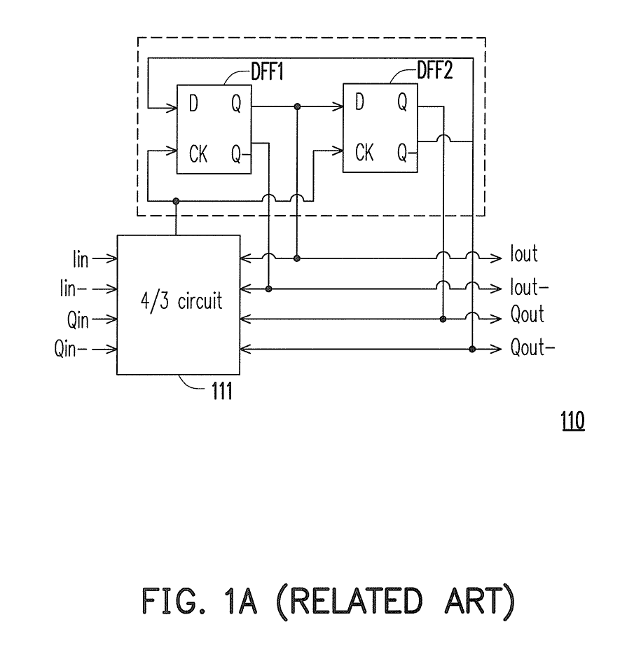

FIG. 1B is a diagram illustrating a divided-by-3 circuit 120 disclosed by a U.S. Pat. No. 6,389,095.

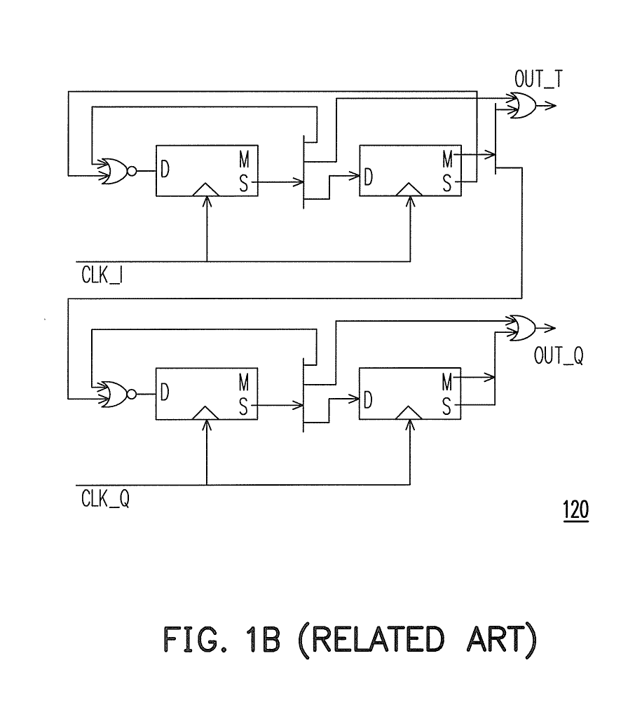

FIG. 2A is a schematic diagram illustrating a multi-phase signals generator 200 according to an embodiment of the present invention.

FIG. 2B is a signal waveform diagram of a multi-phase signals generator 200.

FIG. 3 is a schematic diagram illustrating a multi-phase signals generator 300 according to another embodiment of the present invention.

FIG. 4 is a schematic diagram illustrating a multi-phase signals generator according to still another embodiment of the present invention.

### DESCRIPTION OF THE EMBODIMENTS

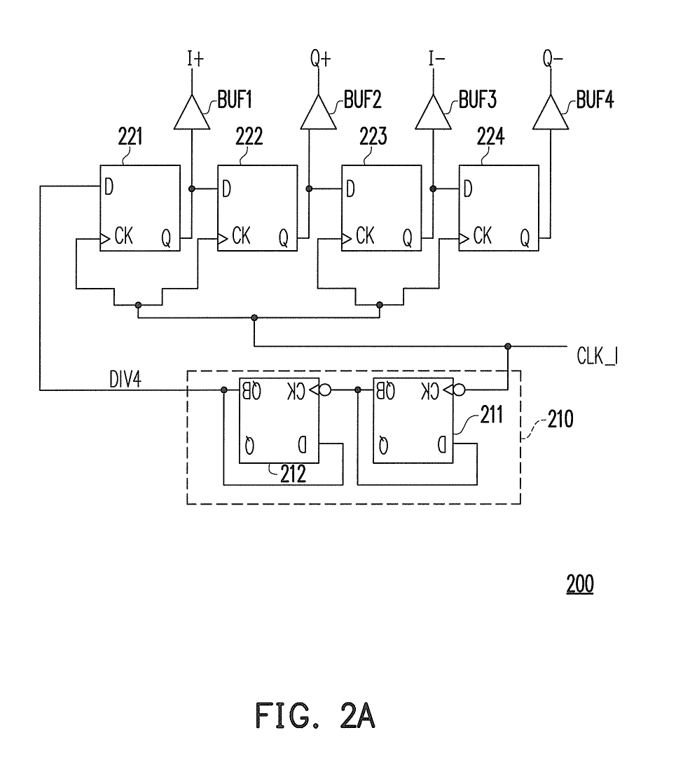

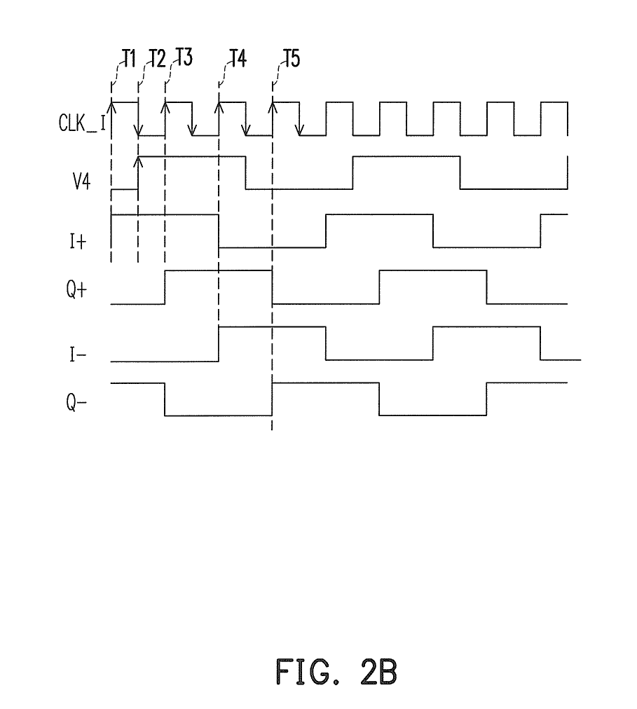

Referring to FIG. 2A first, FIG. 2A is a schematic diagram illustrating a multi-phase signals generator 200 according to an embodiment of the present invention. The multi-phase signals generator 200 includes a frequency divider 210, delay circuits 221, 222, 223 and 224, and output buffers BUF1, BUF2, BUF3 and BUF4. The frequency divider 210 receives a clock signal CLK_I, and divides a frequency of the clock signal CLK_I to generate a divided frequency clock signal DIV4. The delay circuits 221-224 are connected in series. The delay circuit 221 connected in a first stage is coupled to the frequency divider 210 and receives the divided frequency clock signal DIV4. The delay circuit 222 connected in a second stage receives an output of the delay circuit 221 connected in the first stage. Similarly, the delay circuit 223 connected in a third stage receives an output of the delay circuit 222 connected in the second stage, and the delay circuit 224 connected in a fourth stage receives an output of the delay circuit 223 connected in the third stage. Moreover, the delay circuits 221-224 all receive the clock signal CLK_I.

The delay circuits 221-224 delay a received input signal respectively according to the clock signal CLK_I, and generate delay output signals. Since the delay circuits 221-224 are connected in series, and the input signal received by the delay circuit 221 is the divided frequency clock signal DIV4, the delay circuits 221-224 delay the divided frequency clock signal DIV4 sequentially, and generate four delay output signals having different phases correspondingly. Moreover, the phase of the delay output signal generated by the delay circuit 221 is one clock cycle of the clock signal CLK_I in advance compared to the phase of the delay output signal generated by the delay circuit 222, the phase of the delay output signal generated by the delay circuit 222 is in advance to the phase of the delay output signal generated by the delay circuit 223 one clock cycle of the clock signal CLK_I, and the phase of the delay output signal generated by the delay circuit 223 is in advance to the phase of the delay output signal generated by the delay circuit 224 one clock cycle of the clock signal CLK_I.

It should be noticed that for controlling time delays of the delay output signals generated by the delay circuits 221-224 to be equalized accurately, the delay circuits 221-224 have to simultaneously receive the clock signal CLK_I. Therefore, time for transmitting the clock signal CLK_I to each of the delay circuits have to be equal.

In the present embodiment, the delay output signals generated by the delay circuits 221-224 are further transmitted to the output buffers BUF1-BUF4, and the output buffers BUF1-BUF4 generate multi-phase output signals I+, Q+, I− and Q−. It should be noticed that the output buffers BUF1-BUF4 are not necessary devices, and the delay output signals generated by the delay circuits 221-224 can also be directly output to serve as the required multi-phase output signals I+, Q+, I− and Q−.

In the present embodiment, the frequency divider 210 is formed by frequency-dividing units 211 and 212. The frequency-dividing units 211 and 212 are all D-type flip-flops. Each of the D-type flip-flops used for forming the frequency-dividing units 211 and 212 has an input terminal D, an output terminal Q, an inverted output terminal QB and a clock terminal CK, wherein the input terminal D is coupled to the inverted output terminal QB. According to FIG. 2A, it is known that each stage of the frequency-dividing unit can divide a frequency of the received input signal by 2. In other words, the frequency divider 210 including the two frequency-dividing units 211 and 212 can divide the frequency of the clock signal CLK_I by 4 and generate the divided frequency clock signal DIV4.

It should be noticed that the frequency divider 210 of FIG. 2A implemented by two D-type flip-flops connected in series is only an example, which is not used to limit the present invention, and those with ordinary skill in the art should understand that the frequency divider 210 can also be implemented by various approaches such as a counter or T-type flip-flops connected in series.

Moreover, since the multi-phase signals generator 200 of the present embodiment is required to generate four multi-phase output signals having different phases, a divisor that the frequency divider 210 divides the frequency of the clock signal CLK_I by is greater than or equal to 4. Certainly, if the multi-phase signals generator 200 is required to generate more multi-phase output signals (for example, N, and N is an integer greater than 4) having different phases, the divisor that the frequency divider 210 divides the frequency of the clock signal CLK_I by is greater than or equal to N.

The delay circuits 221-224 can also be formed by D-type flip-flops. Similarly, each of the D-type flip-flops used for forming the delay circuits 221-224 has the input terminal D, the output terminal Q and the clock terminal CK. The clock terminal CK of the delay circuit 221 receives the clock signal CLK_I, the input terminal D receives the divided frequency clock signal DIV4, and the output terminal Q outputs the corresponding delay output signal. The clock terminals CK of the delay circuits 222-224 all receive the clock signals CLK_I, each of the input terminals D receives the delay output signal generated by a previous delay circuit, and the output terminals Q output the corresponding delay output signals.

It should be noticed that to avoid a clock skew phenomenon, the D-type flip-flop used for forming the frequency divider 210 is triggered to perform the frequency dividing according to a falling edge of the clock signal CLK_I, and the D-type flip-flops used by the delay circuits 221-224 are triggered according to a rising edge of the clock signal CLK_I.

Referring to FIG. 2A and FIG. 2B, FIG. 2B is a signal waveform diagram of the multi-phase signals generator 200. The frequency divider 210 performs the frequency dividing according to the falling edge of the clock signal CLK_I (a time point T2), and generates the divided frequency clock signal DIV4. The delay circuits 221-224 generate the multi-phase output signals I+, Q+, I− and Q− according to the rising edge of the clock signal CLK_I (time points T1, T3 and T4). According to FIG. 2B, it is known that transition points of the divided frequency clock signal DIV4 and the multi-phase output signals I+, Q+, I− and Q− are effectively interlaced (each difference there between is a quarter of the cycle of the clock signal CLK_I), so that the clock skew phenomenon is avoided.

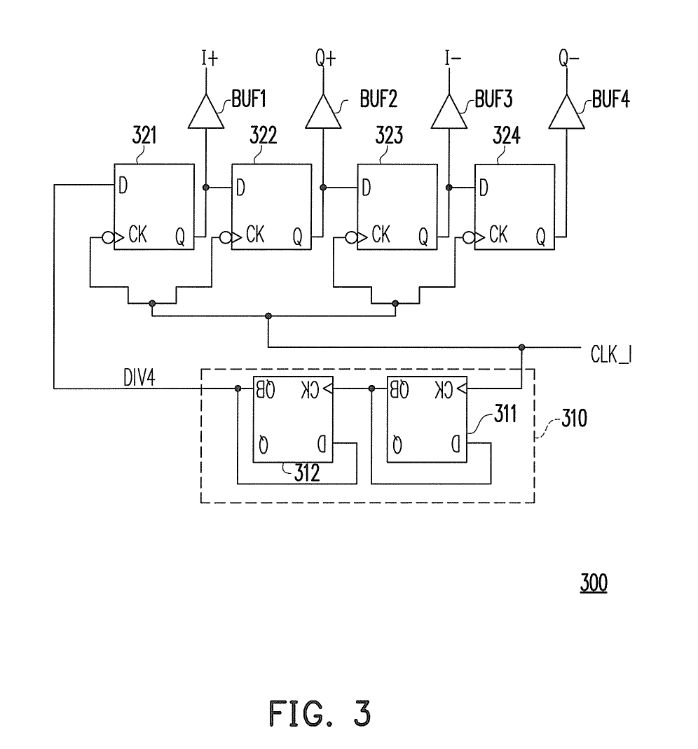

Referring to FIG. 3, FIG. 3 is a schematic diagram illustrating a multi-phase signals generator 300 according to another embodiment of the present invention.

Different from the multi-phase signals generator 200 of FIG. 2A, in the present embodiment, frequency-dividing units 311 and 312 in a frequency divider 310 perform the frequency dividing according to the rising edge of the clock signal CLK_I, and delay circuits 321-324 generate the multi-phase output signals I+, Q+, I− and Q− according to the falling edge of the clock signal CLK_I. Therefore, the frequency divider 310 and the delay circuits 321-324 respectively perform the frequency dividing and delays according to different transition edges (the rising edge and the falling edge) of the clock signal CLK_I, so as to effectively avoid the clock skew phenomenon.

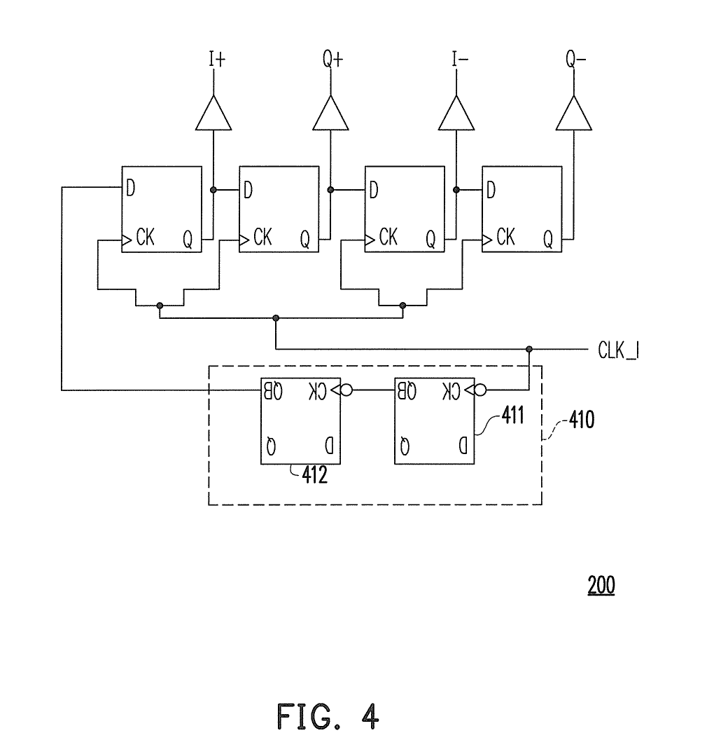

Referring to FIG. 4, FIG. 4 is a schematic diagram illustrating a multi-phase signals generator according to still another embodiment of the present invention. Different to the multi-phase signals generators of FIG. 2A and FIG. 3, in the present embodiment, frequency-dividing units 411 and 412 in a frequency divider 410 are formed by T-type flip-flops. Each of the T-type flip-flops has the input terminal CK and the output terminal Q. The input terminal CK of the frequency-dividing unit 411 receives the clock signal CLK_I, the output terminal Q of the frequency-dividing unit 411 is coupled to the input terminal CK of the frequency-dividing unit 412, and the output terminal Q of the frequency-dividing unit 412 outputs the divided frequency clock signal DIV4.

In summary, in the present invention, the delay circuits simultaneously receive the clock signal, and sequentially delay the divided frequency clock signal according to the simultaneously received clock signal, so as to generate a plurality of the multi-phase output signals having different phases. In the present invention, the multi-phase output signals of at least four phases can be generated only according to the single-end input clock signal, and using of the differential input signals is unnecessary, so that a power consumption of the DC current can be effectively avoided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A multi-phase signals generator, comprising:
a frequency divider, receiving a clock signal and dividing a frequency of the clock signal to generate a divided frequency clock signal; and
N delay circuits, connected in series, wherein the delay circuit connected in a first stage is coupled to the frequency divider and receives the divided frequency clock signal, the delay circuit connected in an i^{th} stage receives an output of the delay circuit connected in an (i−1)^{th} stage, wherein i is an integer larger than 2, the delay circuits respectively delay a received signal according to the clock signal and generate N delay output signals, wherein N is an integer larger than 3,
and a plurality of times for transmitting the clock signal to all of the delay circuits are the same.

2. The multi-phase signals generator as claimed in claim 1, wherein the frequency divider performs a frequency dividing according to a rising edge of the clock signal, and the delay circuit generates one of the delay output signals according to a falling edge of the clock signal.

3. The multi-phase signals generator as claimed in claim 1, wherein the frequency divider performs a frequency dividing according to a falling edge of the clock signal, and the delay circuit generates one of the delay output signals according to a rising edge of the clock signal.

4. The multi-phase signals generator as claimed in claim 1, wherein a divisor provided by the frequency divider is greater than or equal to N.

5. The multi-phase signals generator as claimed in claim 1, wherein the frequency divider comprises:
at least N frequency-dividing units, receiving the clock signal and dividing the frequency of the clock signal to generate the divided frequency clock signal.

6. The multi-phase signals generator as claimed in claim 5, wherein the frequency-dividing unit comprises:
a T-type flip-flop, having an input terminal and an output terminal, wherein the input terminal receives the clock signal, and the output terminal outputs the divided frequency clock signal.

7. The multi-phase signals generator as claimed in claim 5, wherein the frequency-dividing unit comprises:
a D-type flip-flop, having an input terminal, an output terminal, an inverted output terminal and a clock terminal, wherein the input terminal is coupled to the inverted output terminal, and the output terminal outputs the divided frequency clock signal.

8. The multi-phase signals generator as claimed in claim 1, wherein each of the delay circuits comprises:
a D-type flip-flop, having an input terminal, an output terminal and a clock terminal, wherein the clock terminal receives the clock signal, the input terminal receives one of the delay output signals or the divided frequency clock signal, and the output terminal outputs another one of the delay output signals.

9. The multi-phase signals generator as claimed in claim 1, further comprising:
N output buffers, respectively coupled to the delay circuits, the delay circuits receiving the delay output signals to generate N multi-phase output signals.
